(19) United States
(12) Patent Application Publication
(10) Pub. No.: US 2008/0061392 A1
(43) Pub. Date: Mar. 13, 2008

(54) PHOTO-SENSITIVE CHIP MODULE PACKAGE

(75) Inventor: Tzu-Yin YEN, Taichung County (TW)

Correspondence Address: BROWDY AND NEIMARK, P.L.L.C.;624 NINTH STREET, NW, SUITE 300, WASHINGTON, DC, 20001-5303, US

(73) Assignee: Lingsen Precision Industries, Ltd., Taichung (TW)

(21) Appl. No.: 11/764,944

(22) Filed: Jun. 19, 2007

(30) Foreign Application Priority Data
Sep. 8, 2006 (TW) 95216094

(51) Int. Cl. H01L 23/02

(52) U.S. Cl. 257/433; 257/E33.076

(57) ABSTRACT

A photo-sensitive chip module package includes a substrate, a photo-sensitive chip installed on the substrate and having a photo-sensitive zone, a plurality of passive components installed on the substrate, and a plurality of bonding wires electrically connected with the photo-sensitive chip and the passive components to the substrate. A cap is capped on the substrate and defines with the substrate an accommodation chamber that receives the photo-sensitive chip and the passive components. The cap has a light transmissive zone corresponding to the photo-sensitive zone of the photo-sensitive chip for allowing light to stream on the photo-sensitive zone of the photo-sensitive chip.

### BACKGROUND OF THE INVENTION

1. Field of the Invention

The present invention relates to photo-sensitive chips and more particularly, to a photo-sensitive chip module package.

2. Description of the Related Art

Photo-sensitive chips are widely used in various different fields. To enhance the performance and stability of a photo-sensitive chip package, mechanical support strength, environmental factors, such as ambit light, electrical connection condition, heat resistivity, and many other factors must be taken into account during packaging

In a conventional photo-sensitive chip package 1 as shown in FIG. 1, the photo-sensitive chip 2 is packaged at first and then installed with passive components 3 in motherboard 4. This photo-sensitive chip package 1 requires further complicated processing processes, resulting in increase of manufacturing cost and time.

Therefore, it is desirable to provide a photo-sensitive chip module package that eliminates the aforesaid drawbacks.

### SUMMARY OF THE INVENTION

The present invention has been accomplished in view of the above-noted circumstances. It is therefore one objective of the present invention to provide a photo-sensitive chip module package, which simplifies the manufacturing process and saves much the manufacturing cost.

To achieve this objective of the present invention, the photo-sensitive chip module package comprises a substrate, a photo-sensitive chip installed on the substrate and having a photo-sensitive zone, a plurality of passive components installed on the substrate, and a plurality of bonding wires electrically connected with the photo-sensitive chip and the passive components to the substrate. A cap is capped on the substrate and defines with the substrate an accommodation chamber that receives the photo-sensitive chip and the passive components. The cap has a light transmissive zone corresponding to the photo-sensitive zone of the photo-sensitive chip for allowing light to stream on the photo-sensitive zone of the photo-sensitive chip.

The invention has the photo-sensitive chip and the related passive components packaged in the package to simplify the manufacturing process, thereby saving much the manufacturing cost.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIG. 1 is a schematic drawing showing that a photo-sensitive chip package and passive components are installed with a motherboard according to a prior art;

FIG. 2 is a schematic drawing showing a photo-sensitive chip module package according to a preferred embodiment of the present invention; and

FIG. 3 is a schematic drawing showing that the photo-sensitive chip module package is installed with a motherboard according to the preferred embodiment of the present invention.

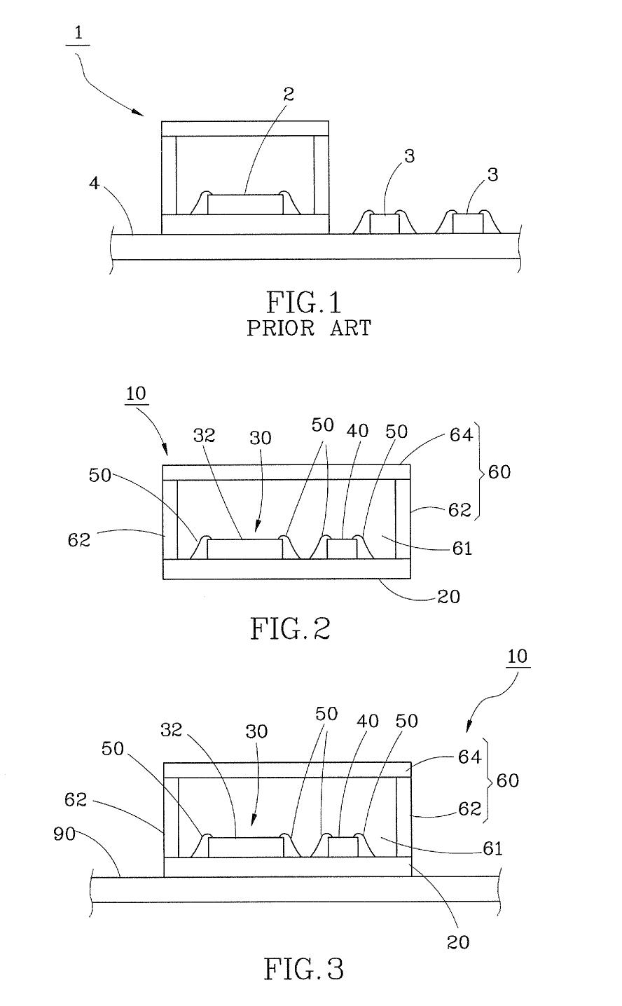

### DETAILED DESCRIPTION OF THE INVENTION

As shown in FIG. 2, a photo-sensitive chip module package 10 in accordance with a preferred embodiment of the present invention comprises a substrate 20, a photo-sensitive chip 30, a plurality of passive components 40, a plurality of bonding wires 50 and a cap 60.

The substrate 20 can be made of epoxy, organic fiber glass substrate, glass fiber board, polyphenylene either, or ceramic. According to this embodiment, the substrate 20 is preferably made of a glass fiber board.

The photo-sensitive chip 30 can be a CCD (charge-coupled device) chip, CMOS (Complementary metal oxide semiconductor) chip, or LED (light emitting diode) chip. According to this embodiment, the photo-sensitive chip 30 is preferably a CMOS chip. The photo-sensitive chip 30 is installed on the substrate 20, having a photo-sensitive zone 32 at the center.

The passive components 40 are arranged on the substrate 20 to provide a particular function to the photo-sensitive chip 30.

The bonding wires 50 are used to electrically connect the photo-sensitive chip 30 and the passive components 40 to the substrate 30 for enabling the photo-sensitive chip 30 to provide particular functions through the passive components 40.

The cap 60 is covered on the substrate 20, defining an accommodation chamber 61 that accommodates the photo-sensitive chip 30 and the passive components 40. The cap 60 is formed of multiple plate members that are joined with one another. The cap 60 has an opaque zone 62 and a light transmissive zone 64. The opaque zone 62 surrounds the light transmissive zone 64. The light transmissive zone 64 is formed of a light transmissive glass, facing the photo-sensitive zone 32 of the photo-sensitive chip 30 so that light can pass through the light transmissive zone 64 and stream on the photo-sensitive zone 32.

Subject to the aforesaid arrangement, the photo-sensitive chip module package 10 according to the preferred embodiment of the present invention is done through one single processing process. Compared to the prior art design, the photo-sensitive chip module package 10 has a relatively smaller dimension. Further, the passive components 40 can provide particular functions to the photo-sensitive chips 30 without through a secondary processing process. Therefore, the invention has the characteristics of simple structure and low manufacturing cost. Further, the cap 60 limits the detection range of the photo-sensitive chip 30, lowering the interference of environmental noises, i.e., the photo-sensitive chip module package 10 has better stability.

FIG. 3 illustrates the photo-sensitive chip module package 10 installed on a motherboard 90. By means of one single packaging process, the photo-sensitive chip module package 10 has the photo-sensitive chip 30 and the related passive components 40 contained on the inside for quick installation on the motherboard 90. The application of the present invention requires less motherboard space, and saves much the electronic device manufacturing time and cost.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A photo-sensitive chip module package comprising:
a substrate;
a photo-sensitive chip installed on the substrate and having a photo-sensitive zone;
a plurality of passive components installed on the substrate;
a plurality of bonding wires electrically connected with the photo-sensitive chip and the passive components to the substrate; and
a cap capped on the substrate and defining with the substrate an accommodation chamber that receives the photo-sensitive chip and the passive components, the cap having a light transmissive zone corresponding to the photo-sensitive zone of the photo-sensitive chip for allowing light to stream on the photo-sensitive zone of the photo-sensitive chip.

2. The photo-sensitive chip module package as claimed in claim 1, wherein the cap is formed of multiple plate members that are joined with one another.

3. The photo-sensitive chip module package as claimed in claim 1, wherein the light transmissive zone of the cap is formed of a light transmissive glass.

4. The photo-sensitive chip module package as claimed in claim 1, wherein the cap comprises an opaque zone surrounding the light transmissive zone.

5. The photo-sensitive chip module package as claimed in claim 1, wherein the photo-sensitive chip is a charge-coupled device chip, a complementary metal oxide semiconductor chip or a light emitting diode chip.
